(19) United States
(12) Patent Application Publication
(10) Pub. No.: US 2025/0202454 A1
(43) Pub. Date: Jun. 19, 2025

(54) PACKAGED INTEGRATED CIRCUIT INCLUDING SEMICONDUCTOR DIE AND PIEZOELECTRIC RESONATOR

(71) Applicant: TEXAS INSTRUMENTS INCORPORATED, Dallas, TX (US)

(72) Inventors: Sombuddha Chakraborty, Redwood City, CA (US); Jeronimo Segovia-Fernandez, San Jose, CA (US); Kashyap Mohan, Irving, TX (US); Eric Stolt

(21) Appl. No.: 18/389,626

(22) Filed: Dec. 19, 2023

(51) Int. Cl. H03H 9/15; H01L 23/00; H02M 3/00; H03H 9/13

(52) U.S. Cl. CPC H03H 9/15; H02M 3/003; H03H 9/13; H01L 24/16; H01L 2224/16227

(57) ABSTRACT

A packaged integrated circuit (IC) includes a package substrate having opposing first and second surfaces. The package substrate includes first and second metal pads on the first surface, third metal pads on the second surface, and metal interconnects coupled between the third metal pads and at least some of the first and second metal pads. A semiconductor die is on the first surface and is coupled to the first metal pads. Metal support structures are on the first surface and are coupled to a at least some of the second metal pads. A piezoelectric resonator is on the metal support structures and over the semiconductor die. A cap is on the package substrate and covers the piezoelectric resonator, the metal support structures, and the semiconductor die.

### BACKGROUND

A power converter, such as a switch-mode power converter, converts an input voltage into an output voltage to power a load. In some examples, the power converter includes a half bridge and an inductor, which is switched by the half bridge between receiving and storing energy stages from a power source and releasing the stored energy to the load. The inductor is fairly large and has a large profile/height and a large footprint, which can cause the overall height and footprint of the power converter to be large.

### SUMMARY

In one example, a packaged integrated circuit (IC) includes a package substrate having opposing first and second surfaces. The package substrate includes first and second metal pads on the first surface, third metal pads on the second surface, and metal interconnects coupled between the third metal pads and at least some of the first and second metal pads. A semiconductor die is on the first surface and is coupled to a first subset of the first metal pads. Metal support structures are on the first surface and are coupled to a second subset of the first metal pads. A piezoelectric resonator is on the metal support structures and over the semiconductor die. A cap is on the package substrate and covers the piezoelectric resonator, the metal support structures, and the semiconductor die.

In another example, a power converter includes at least an input terminal, an output terminal, a ground terminal, and a package substrate. The power converter may also include a controller coupled to the package substrate. First and second metal support structures are coupled to the package substrate. A piezoelectric resonator is attached to the first and second metal support structures and over the controller. The piezoelectric resonator is coupled to the controller through the package substrate.

In yet another example, a method of forming a packaged IC includes attaching a semiconductor die on a first surface of a package substrate, in which the semiconductor die is coupled to a first subset of the first metal pads. The package substrate has the first surface and an opposing second surface. The package substrate also includes first and second metal pads on the first surface, third metal pads on the second surface, and metal interconnects coupled between the third metal pads and at least some of the first and second metal pads. The method further includes attaching metal support structures on the first surface, in which the metal support structures are coupled to a second subset of the first metal pads. The method also includes attaching a piezoelectric resonator on the metal support structures and over the semiconductor die and attaching a cap on the package substrate. The cap covers the piezoelectric resonator, the metal support structures, and the semiconductor die.

### BRIEF DESCRIPTION OF THE DRAWINGS

FIG. 1 is a schematic diagram of a power converter including a piezoelectric resonator in an example.

FIG. 2 is a schematic diagram illustrating a cross-sectional view of a packaged IC including a piezoelectric resonator, in an example.

FIGS. 3 and 4 are schematic diagrams illustrating perspective views of a packaged IC including a piezoelectric resonator, in an example.

FIGS. 5A and 5B are schematic diagrams illustrating cross-sectional views of a packaged IC including a piezoelectric resonator, in accordance with another example.

FIG. 6A is a schematic diagram illustrating a top-down view of a package substrate of a packaged IC including a piezoelectric resonator, in an example

FIG. 6B is a graph illustrating the performance of the piezoelectric resonator mounted on the package substrate of FIG. 6a, in an example.

FIG. 7A is a schematic diagram illustrating a top-down view of a package substrate of a packaged IC including a piezoelectric resonator, in another example

FIG. 7B is a graph illustrating the performance of the piezoelectric resonator mounted on the package substrate of FIG. 7A, in an example.

FIGS. 8, 9, 10, 11, and 12 are schematic diagrams illustrating cross-sectional views of a packaged IC including a stack of piezoelectric resonators, in various examples.

FIG. 13 is a schematic diagram of a transformer including a primary stack of piezoelectric resonators and a secondary stack of piezoelectric resonators, in an example.

FIGS. 14, 15, 16, 17, 18, and 19 are schematic diagrams illustrating cross-sectional views at various stages of manufacturing of a packaged IC including a piezoelectric resonator, in an example.

FIG. 20 is a flowchart of the manufacturing operations of FIGS. 14-19, in an example.

### DETAILED DESCRIPTION

The same reference numbers or other reference designators are used in the drawings to designate the same or similar (either by function and/or structure) features.

The power converter described herein can include a switching power converter having a piezoelectric resonator. Piezoelectric components, such as piezoelectric resonators and transformers, store energy as mechanical inertia that can be readily transduced to electrical energy and have shown high promise in achievable power density and energy transfer efficiency. Electrically, piezoelectric materials such as lithium niobate (LN) and lead zirconium titanate (PZT) offer extremely high energy density and a high quality factor as compared with inductors, and piezoelectric components provide natural mechanisms for galvanic isolation. From a manufacturing standpoint, piezoelectric components exhibit improved scaling properties as compared with magnetic core components, have planar form factors, and can be fabricated compatibly with batch semiconductor manufacturing processes. Accordingly, by integrating a piezoelectric resonator with a bridge circuit as part of a power converter in a packaged IC, the overall size/volume of the packaged IC can be reduced. In the disclosed examples, the piezoelectric resonator is mounted over a semiconductor die (e.g., a controller) on a package substrate, which can further reduce the footprint of the packaged IC, while the increase in the height/profile of the packaged IC due to the stacking of the semiconductor die and the piezoelectric resonator can be minimal due to the low profile of the piezoelectric resonator. Accordingly, by packaging together the semiconductor die and the piezoelectric resonator, the overall size (and profile) of the resulting power converter can be reduced compared to power converters having inductors, which can increase the power density of the power converter.

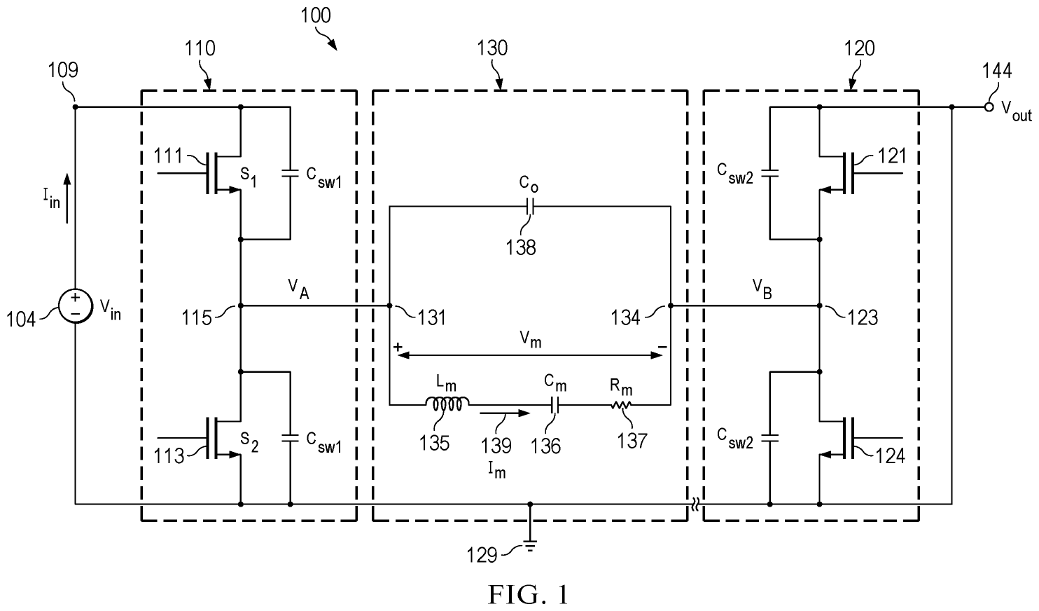

FIG. 1 is a schematic diagram of a power converter 100 in an example. Power converter 100 includes an input power terminal 109, an output power terminal 144, and a ground terminal 129. Power converter 100 converts an input voltage Vin 104 at its input power terminal 109 into an output voltage Vout at its output power terminal 144. Output voltage Vout may be larger or smaller than input voltage Vin. Power converter 100 includes a first half-bridge 110, a second half-bridge 120, and a piezoelectric resonator 130 coupled between the first and second half-bridges 110 and 120. Half-bridge 110 includes transistors or switches 111 and 113 coupled in series between the input power terminal 109 and the ground terminal 129. Half-bridge 120 includes transistors or switches 121 and 124 coupled in series between the output power terminal 144 and the ground terminal 129. Transistors 111, 113, 121, and 124 can be n-channel field effect transistors (NFETs) as shown in the example of FIG. 1 or other types of transistors. Each transistor includes a parasitic capacitance—transistors 111 and 113 having a parasitic capacitance Csw1, and transistors 121 and 124 having a parasitic capacitance Csw2.

The piezoelectric resonator has electrodes 131 and 134. Electrode 131 can be a positive electrode and is coupled to the switching terminal 115 between the source of transistor 111 and the drain of transistor 113. Electrode 134 can be a negative electrode and is coupled to the switching terminal 123 between the source of transistor 121 and the drain of transistor 124. Piezoelectric resonator 130 is represented in FIG. 1 based on the Van Dyke model. The mechanical resonance of piezoelectric resonator 130 is represented by the motional branch including the inductance 135 (Lₘ) capacitance 136 (Cₘ), and resistance 137 (Rₘ). The static input capacitance of the piezoelectric material is modeled as a parallel capacitance 138 (C₀). Current through the series branch is denoted in FIG. 1 as current Iₘ 139. The voltage across electrodes 131 and 134 is denoted Vₘ in FIG. 1.

A controller (not shown in FIG. 1 but shown in other figures) has outputs coupled to the gates of transistors 111, 113, 121, and 124 and controls the on and off states of the transistors. The switching pattern and timing implemented by the controller determines the conversion ratio between the input voltage Vin and the output voltage Vout.

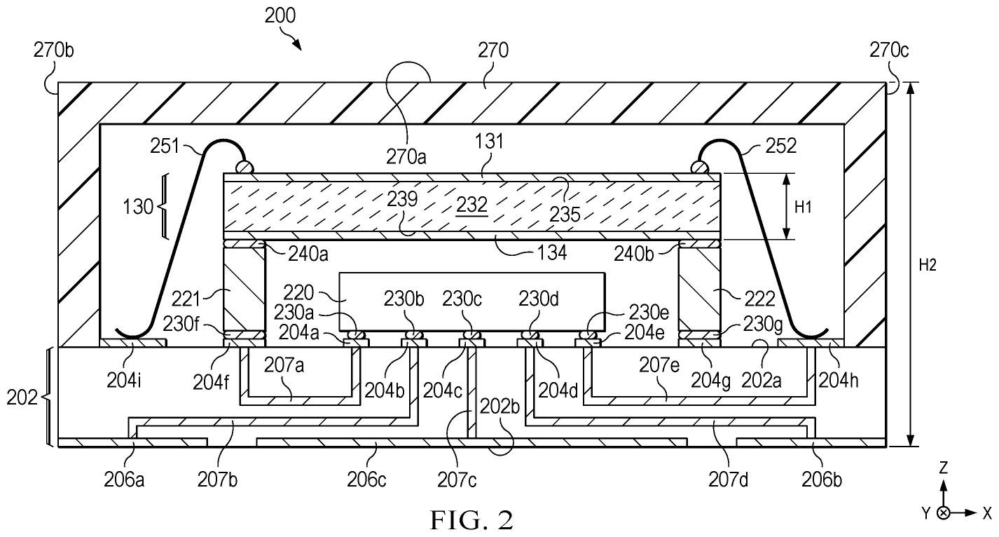

FIG. 2 is cross-sectional of a packaged integrated circuit (IC) 200, which can implement power converter 100 in an example. Packaged IC 200 includes a package substrate 202, a semiconductor die 220, metal support structures 221 and 222, piezoelectric resonator 130, and a cap 270. In some examples, the package substrate 202 is a leadframe. The package substrate 202 has opposing surfaces 202a and 202b. The package substrate 202 has metal pads 204, such as metal pads 204a, 204b, 204c, 204d, 204e, 204f, 204g, 204h, and 204i, on surface 202a. The package substrate also has metal pads 206, such as metal pads 206a, 206b, and 206c, on surface 202b. Any suitable number of metal pads 204 and 206 can be provided on surfaces 202a and 202b. The package substrate 202 includes metal interconnects 207 to provide electrical connections between metal pads 204 and 206. For example, metal interconnect 207a is electrically coupled between metal pads 204a and 204f. Metal interconnect 207b is electrically coupled between metal pads 204b and 206a. Metal interconnect 207c is electrically coupled between metal pads 204c and 206c. Metal interconnect 207d is electrically coupled between metal pads 204d and 206b. Metal interconnect 207e is electrically coupled between metal pads 204e and 204h. Metal pads 206 provide electrical connections between various components of the packaged IC 200 and an external system (e.g., a printed circuit board (PCB)). For example, metal pad 206a can represent the input power terminal 109 of FIG. 1 (to receive an input voltage Vin), metal pad 206b can represent the output power terminal 144 of FIG. 1 (to provide an output voltage Vout), and metal pad 206c can represent the ground terminal 129 of FIG. 1. Moreover, metal pads 204a and 204f can provide electrical connections between an electrode of the piezoelectric resonator 130 (e.g., electrode 131 of FIG. 1) and the semiconductor die 222. Also, metal pads 204e and 204g can provide electrical connections between another electrode of the piezoelectric resonator 130 (e.g., electrode 134 of FIG. 1) and the semiconductor die 222.

Semiconductor die 220 may include circuitry (e.g., digital components, analog components, a processor, etc.) that implements the controller described above, such as half-bridges 110 and 120. Semiconductor die 220 is on surface 202a of package substrate 202 and is mounted on and electrically coupled to metal pads 204a-204e. Semiconductor die 220 may be a flip-chip and mounted on the metal pads 204 by solder balls or metal pillars 230, such as 230a, 230b, 230c, 230d, and 230e.

In the example of FIG. 1, metal support structures 221 and 222 are on opposing sides of semiconductor die 220. Metal support structures 221 and 222 may include metal posts, sheets, rings, etc. In one example, metal support structures 221 and 222 include copper but can also include other types of metal. Metal support structures 221 and 222 are mounted on and electrically coupled to, respectively, metal pads 204f and 204g via solder layers 230f and 230g.

Piezoelectric resonator 130 is on and supported by the metal support structures 221 and 222. Piezoelectric resonator 130 is over the semiconductor die 220. In this example, the piezoelectric resonator's electrodes 131 and 134 are provided on respective top and bottom surfaces of a piezoelectric material 232 and are referred to herein as the top electrode 131 and the bottom electrode 134. In this example, bond wire(s) 252 is electrically coupled between the top electrode 131 to metal pad 204h. Bond wire(s) 251 can be electrically coupled between the top electrode 131, or another electrode as to be described below, and metal pad 204i. Ribbon bonding and clip bonding can be used as alternatives to bond wires. Bottom electrode 134 is electrically coupled to the metal support structures 221 and 222 by solder layers 240a and 240b and, accordingly, through metal support structures 221 and 222 to metal pads 204e and 204f of the package substrate 202. The top electrode may be a positive electrode, and the bottom electrode may be a negative electrode. The piezoelectric material 232 can include lead zirconate titanate (PZT), lithium niobate (LN), quartz, lithium tantalate, lead titanate, and/or gallium orthophosphate.

Cap 270 is on the package substrate 202 and covers the piezoelectric resonator 130, the metal support structure 221 and 222, and the semiconductor die 220. Cap 270 includes a top 270a and sides 270b and 270c generally orthogonal to top 270a. Cap 270 includes four sides but only sides 270b and 270c are shown in FIG. 2 so that the interior of packaged IC 200 can be seen. Cap 270 may include metal, silicon or fiberglass laminate. Cap 270 can be hermetically sealed to the package substrate and protect the piezoelectric resonator 130 and semiconductor die 220. The gas under cap 270 may be air or any suitable inert gas. The gas may have a relatively low pressure, e.g., 1 Torr.

The height of piezoelectric resonator 130 is height H1. Height H1 is relatively small for a piezoelectric resonator (e.g., 0.5 mm). Because the thin piezoelectric resonator 130 is stacked over the semiconductor die 220 to form a packaged IC, packaged IC 200 has a small footprint on a printed circuit board (PCB), and the height H2 of the packaged IC 200 is advantageously small as well. Height H2 may be in the range of, for example, 0.1 mm to 0.3 mm.

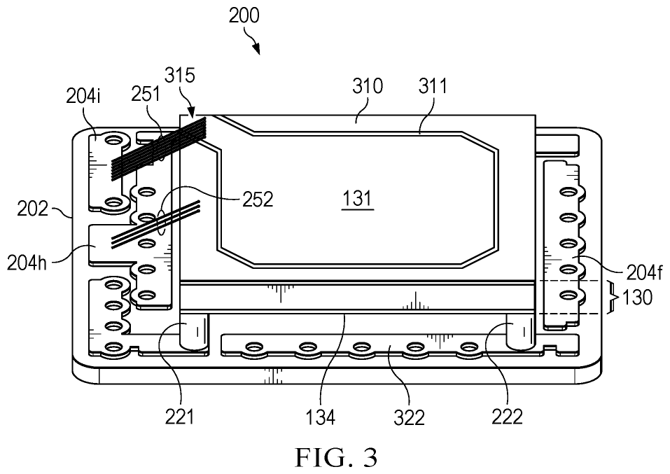

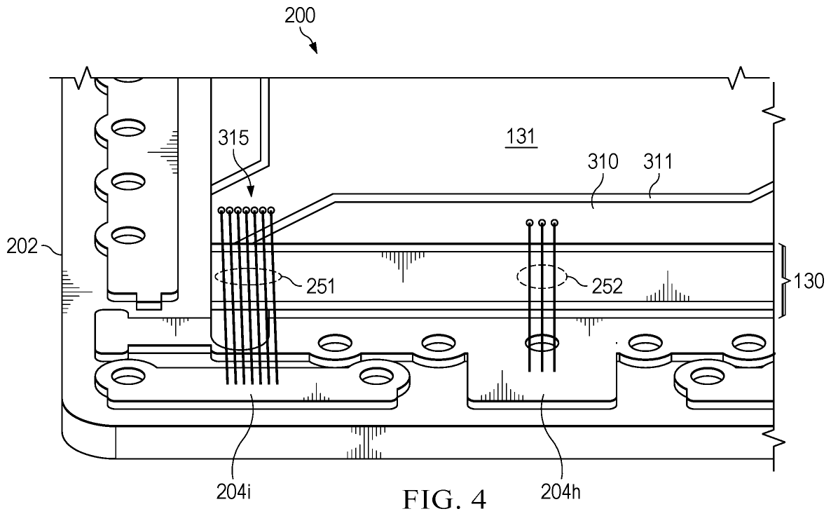

FIGS. 3 and 4 provide perspective views of packaged IC 200. In this example, top electrode 131 is partially surrounded by another electrode, such as a metal ring 310, on the same surface of the piezoelectric material 232 that includes the top electrode 131. The metal ring 310 is electrically isolated from the top electrode 131 by an isolation barrier 311, which may be a separation between the metal ring 310 and the electrode 131. The metal ring 310 can be electrically coupled to the ground terminal via, for example, bond wire 251 and metal pad 204i. A ribbon bond and a clip bond can be used as alternatives to the bond wire. The metal ring 310 helps to trap energy within the piezoelectric material.

In the example of FIGS. 3 and 4, the top electrode 131 includes a portion 315 at or near a corner of the piezoelectric resonator. One or more bond wires 251 electrically couple that portion of the top electrode 131 to metal pad 204g. Bond wire(s) 252 on the opposite of piezoelectric resonator 130 shown in FIG. 2 may or may not be included. In the example of FIGS. 3 and 4, bond wires 252 are not included.

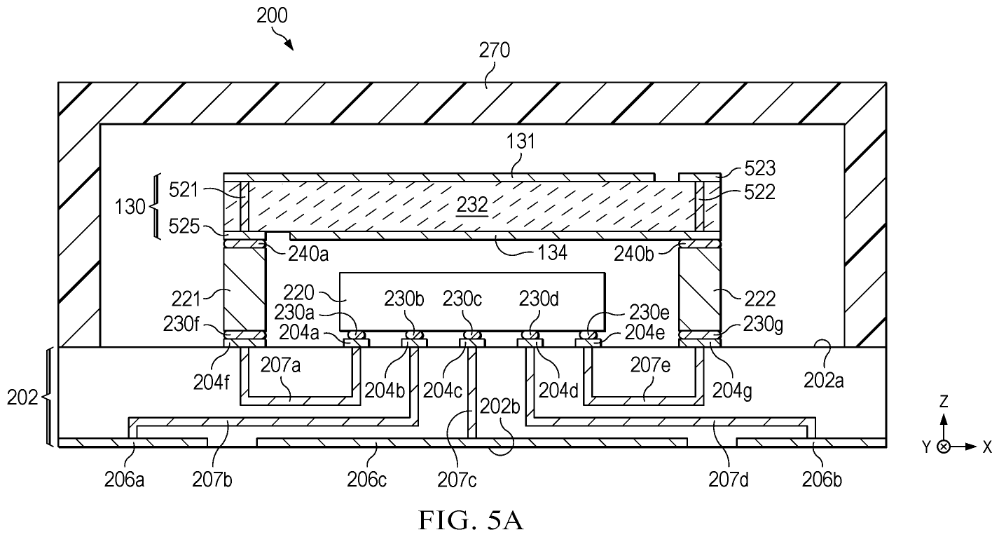

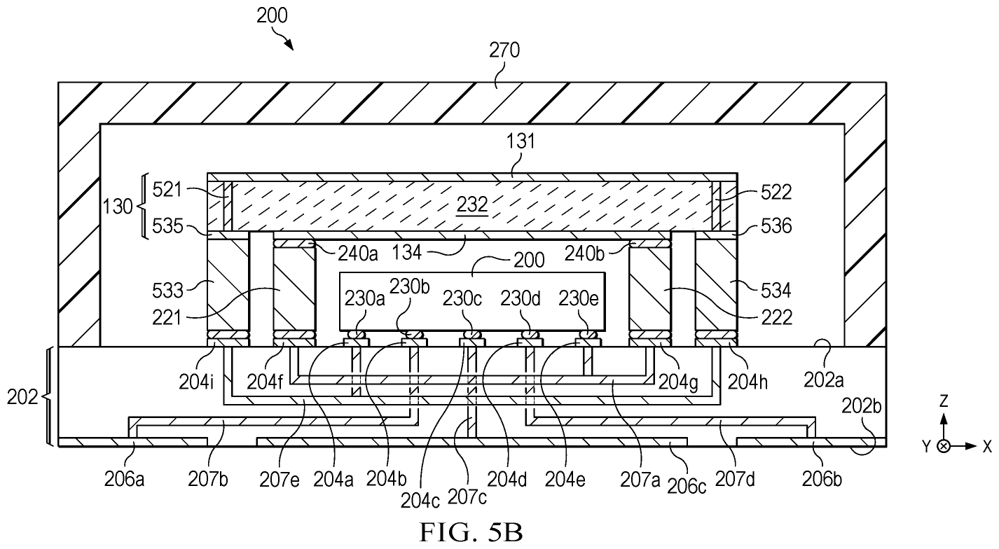

FIGS. 5A and 5B are cross-sectional views of various example of packaged IC 200 which does not include bond wires, ribbons, or clips to electrically couple top electrode 131 to the metal pads on the package substrate 202. FIG. 5A and FIG. 5B may represent two different configurations. FIG. 5A represents an example of packaged IC 200 having a pair of metal support structures 221 and 222, with metal post 221 electrically coupled to top electrode 131 and metal post 222 electrically coupled to bottom electrode 134. FIG. 5B represents an example of packaged IC 200 having a pair of inner metal posts 221 and 222 coupled to bottom electrode 134 and a pair of outer metal support structures (e.g., metal posts) 533 and 534 coupled to top electrode 131. In the example of FIG. 5B, metal interconnect 207a can be c

The packaged IC 200 represented on FIG. 5B can be more symmetric than the packaged IC 200 represented on FIG. 5A.

Referring to FIG. 5A and FIG. 5B, piezoelectric resonator 130 may include metal vias 521 and 522. In FIG. 5A, the metal layer on top of piezoelectric resonator 130 is patterned to form top electrode 131 and top metal layer 523, and the metal layer on bottom of piezoelectric resonator 130 is patterned to form bottom electrode 134 and bottom metal layer 525. The patterning can provide insulation between metal support structures 221 and 222. In FIG. 5A, top electrode 131 is electrically coupled to metal support structure 221 by way of metal via 521 and bottom metal layer 525, and metal support structure 221 is mounted on metal pad 204f. Bottom electrode 134 is electrically coupled to metal support structure 222, and metal via 522 is coupled between top metal layer 523 and metal support structure 222. There can be solder layers between bottom metal layer 525 and metal support structure 221 and between bottom electrode 134 and metal support structure 222, which are not shown in FIG. 5A. In some examples, top metal layer 523 can include metal ring 310, and metal via 522 can provide electrical connection to metal ring 310 to the ground terminal via, for example, metal support structure 222 or another metal support structure not shown in FIG. 5A. Metal interconnect 207a is electrically coupled between metal pads 204a and 204f to provide an electrical connection between the top electrode 131 and the semiconductor die 220, and metal interconnect 207e is electrically coupled between metal pads 204e and 204g to provide an electrical connection between the bottom electrode 134 and the semiconductor die 220.

Also, referring to FIG. 5B, top electrode 131 is electrically coupled to outer metal post 533 by way of metal via 521 and to outer metal support structure 534 by way of metal via 522. Outer metal post 533 can be mounted on and electrically coupled to metal pad 204i, and outer metal support structure 534 can be mounted on and electrically coupled to metal pad 204h. A bottom metal layer on piezoelectric resonator 130 can be patterned into bottom electrode 134 and metal layers 535 and 536. Metal via 521 can be electrically coupled between top electrode 131 and metal layer 535, and metal via 522 can be electrically coupled between top electrode 131 and metal layer 536. There can be solder layers between metal via 521 and metal post 533 and between metal via 522 and metal post 534, which are not shown in FIG. 5B. Bottom electrode 134 is electrically coupled to inner metal posts 221 and 222 and metal pads 204f and 204g. Metal interconnect 207a is electrically coupled between metal pads 204a, 204i, and 204g to provide an electrical connection between the top electrode 131 and the semiconductor die 220, and metal interconnect 207e is electrically coupled between metal pads 204e, 204f, and 204g to provide an electrical connection between the bottom electrode 134 and the semiconductor die 220.

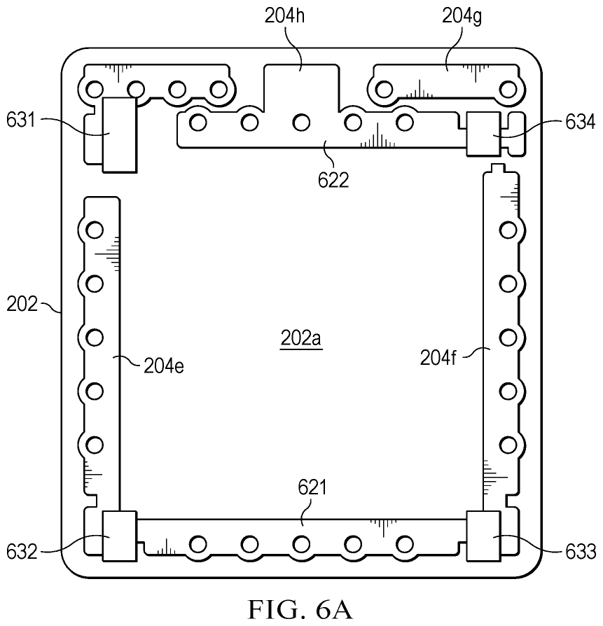

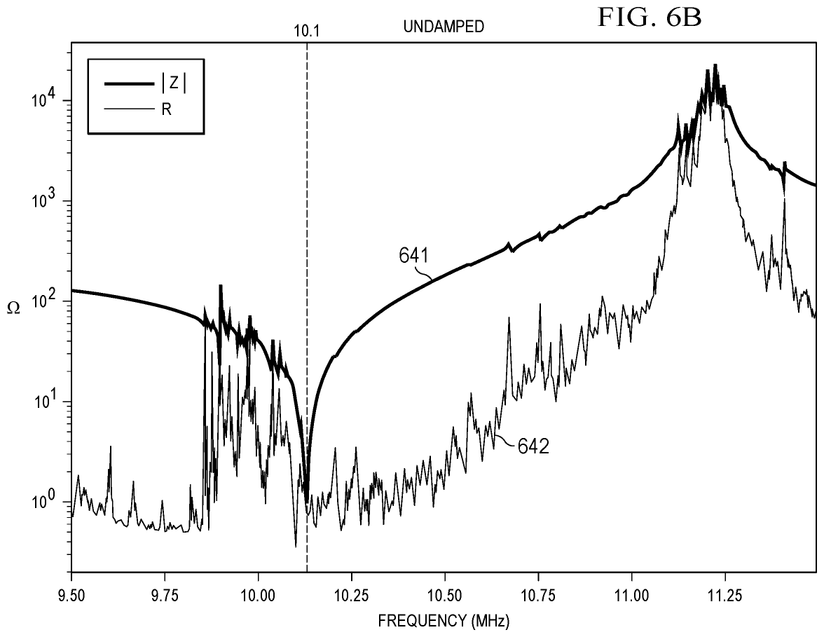

FIG. 6a is a top-down view of surface 202a of the package substrate 202. Metal pads 204e and 204f are shown along with additional metal pads 621 and 622 on package substrate 202. Metal pads 204e, 204f, 621, and 622 may be arranged in a rectangular arrangement as shown in the example of FIG. 6a. Metal support structures 631, 632, 633, and 634 (any of which may correspond to metal support structures 221 and 222) may be provided at the four corners of the rectangular arrangement of metal pads 204e, 204f, 621, and 622. The bottom electrode 134 of the piezoelectric resonator 130 may be soldered to the metal support structures 631, 632, 633, and 634.

The metal support structures 631, 632, 633, and 634 mechanically support the piezoelectric resonator 130 while allowing the piezoelectric resonator 130 to sufficiently vibrate. FIG. 6b is a graph illustrating the performance of the piezoelectric resonator 130 mounted on package substrate 202 at the four corner support structures of FIG. 6a. Plots 641 and 642 illustrate the impedance and resistance response, respectively, of the piezoelectric resonator with respect to frequency. The responses illustrate a resonance at approximately 10.1 MHz. The vibration of the piezoelectric resonator 130 is either not dampened, or dampened only very slightly, with the mounting arrangement of FIG. 6a as indicated by the spurious frequency components of plot 642.

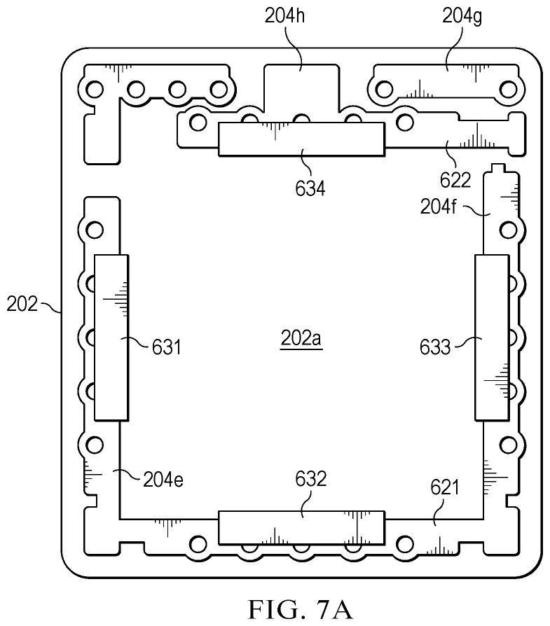

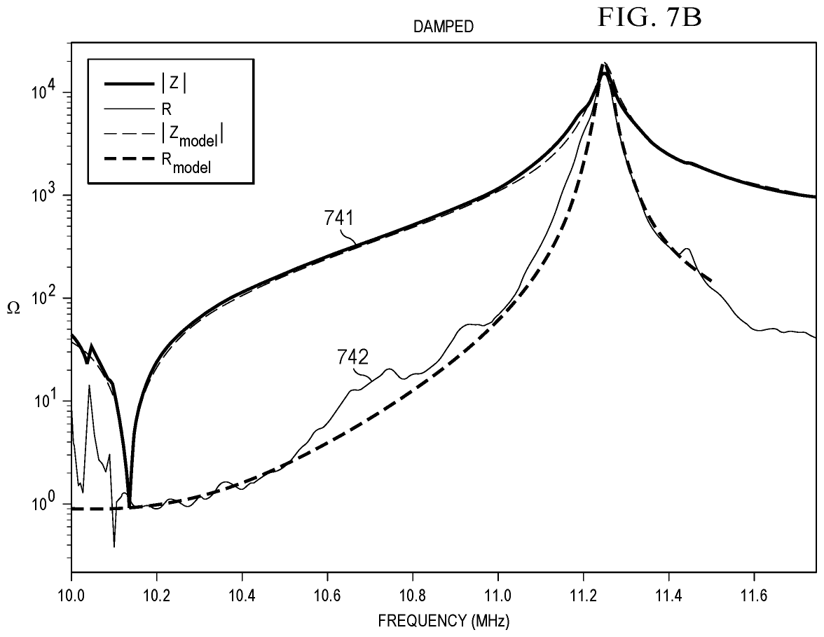

FIG. 7a is a top-down view of surface 202a of the package substrate 202 in another example. In this example, the metal support structures 631, 632, 633, and 634 are provided at the sides of the piezoelectric resonator 130, e.g., approximately at the centers of metal pads 204e, 204f, 621, and 622. Accordingly, the metal support structures are 631, 632, 633, and 634 are below the edge of piezoelectric resonator 130. Supporting the piezoelectric resonator 130 damps to a degree the vibrations of the piezoelectric resonator as indicated by plots 741 and 742 in FIG. 7b. Plots 741 and 742 illustrate the impedance and resistance response, respectively, of the piezoelectric resonator with respect to frequency for the arrangement of FIG. 7a. Comparing plots 741 and 742 of FIG. 7b to plots 641 and 642 of FIG. 6b shows that there are less spurious in the frequency response of the piezoelectric resonator 130 when supported along its sides than at its corners.

In some examples, packaged IC 200 can include multiple piezoelectric resonators vertically stacked over semiconductor die 220. For example, multiple piezoelectric resonators may be provided within packaged IC 200 and coupled together in parallel to increase the effective parallel capacitance 138 C₀ and reduce the effective resistance 137 Rₘ (FIG. 1). By coupling piezoelectric resonators in parallel, the effective parallel capacitance 138 C₀ is the sum of the parallel capacitances 138 of the individual piezoelectric resonators, and the effective resistance 137 Rₘ is the parallel combination of the resistances Rₘ of the individual resonators. A higher effective parallel capacitance 138 C0 and lower effective resistance Rₘ allows for the power converter 100 to provide higher output current and higher power for the same size footprint of packaged IC 200.

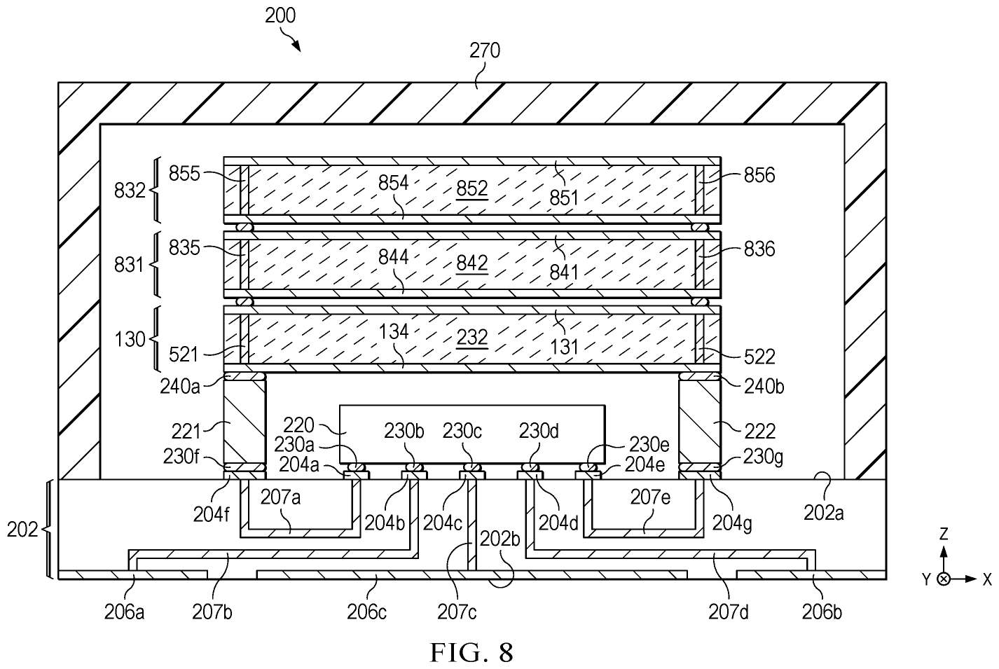

FIG. 8 is a cross-sectional view of a packaged IC 200 including multiple stacked piezoelectric resonators. In this example, three piezoelectric resonators 131, 831, and 832 are included, although in other examples, two or more than three piezoelectric resonators can be included. Cap 270 is on package substrate 202 and covers all three piezoelectric resonators 131, 831, and 832. Piezoelectric resonator 831 includes top and bottom electrodes 841 and 844, respectively, and top metal layer 842 and bottom metal layer 843. Piezoelectric resonator 831 also includes a metal via 833 electrically coupled between top electrode 841 and bottom metal layer 843, and a metal via 836 electrically coupled between top metal layer 842 and bottom electrode 844. Also, piezoelectric resonator 832 includes top and bottom electrodes 851 and 854, respectively, and top metal layer 853 and bottom metal layer 855. Piezoelectric resonator 832 also includes a metal via 855 electrically coupled between top electrode 851 and bottom metal layer 853, and a metal via 856 electrically coupled between top metal layer 852 and bottom electrode 854. In the example of FIG. 8, top electrodes 851, 841, and 131 are electrically coupled to metal support structure 221 by way of metal vias 855, 835, and 521. Also, bottom electrodes 854, 844, and 134 are electrically coupled to metal support structure 222 by way of metal vias 856, 836, and 522.

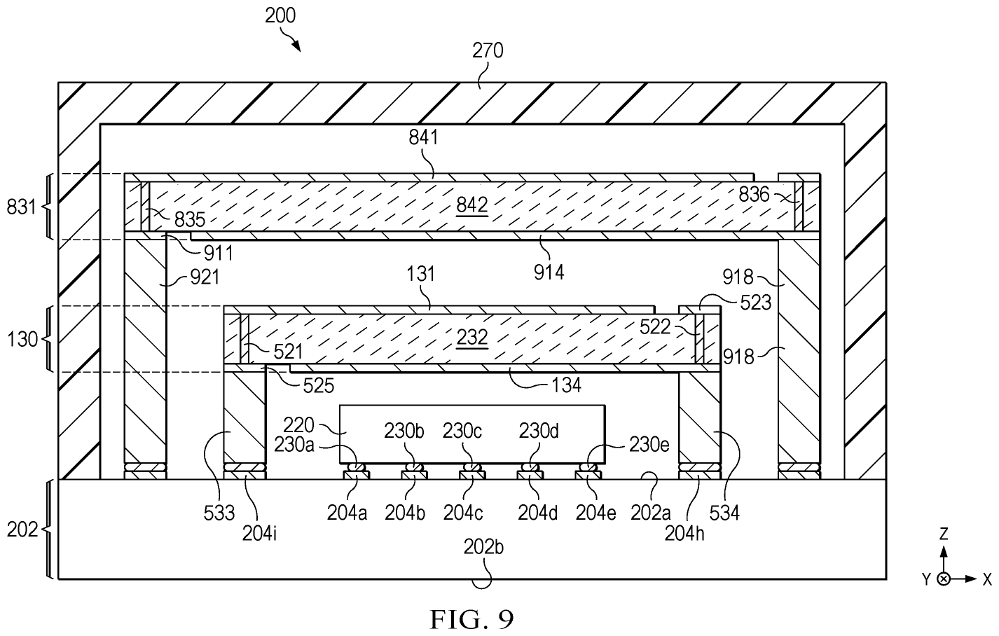

FIG. 9 is a cross-sectional view of a packaged IC 200 that includes two stacked piezoelectric resonators 130 and 831. The upper piezoelectric resonator 831 includes a top electrode 841 and a bottom electrode 844 on either side of piezoelectric material 842 (e.g., PZT, LN, lithium tantalate, lead titanate, and/or gallium orthophosphate). The top electrode 131 of piezoelectric resonator 130 is electrically coupled to metal support structure 533 by metal via 521, and the bottom electrode 134 is electrically coupled to metal support structure 534. Also, top electrode 841 of piezoelectric resonator 831 is coupled to a metal support structure 921 by way of a metal via 835 through piezoelectric resonator 831, and bottom electrode 844 is coupled to a metal support structure 918. Metal support structures 918 and 921 are mounted on metal pads of package substrate 202 (not shown in FIG. 9). Access to the individual top and bottom electrodes of piezoelectric resonators 130 and 831 of FIG. 9 permits the resonators to be connected in parallel or series as desired for a given application.

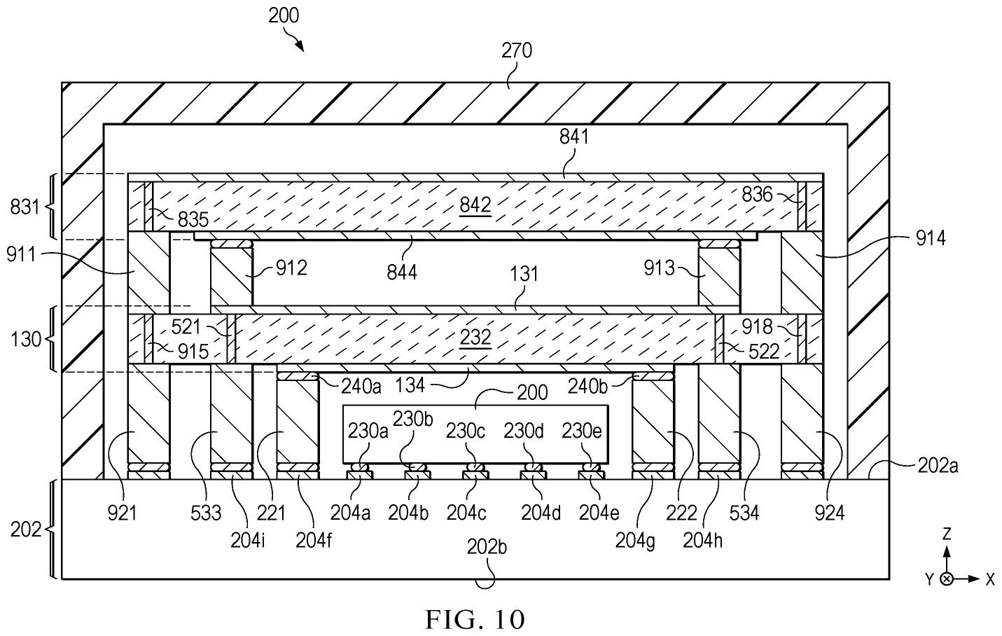

FIG. 10 is a cross-sectional view of the packaged IC 200 in which piezoelectric resonators 131 and 831 are connected in series through internal to the packaged IC. The bottom electrode 844 of upper piezoelectric resonator 831 is electrically coupled directly to the top electrode of piezoelectric resonator 131 by metal support structures 912 and 913. The top electrode 841 of piezoelectric resonator 831 and the top and bottom electrodes 131 of 134 of piezoelectric resonator 130 are electrically coupled to metal pads on package substrate 202 as described above.

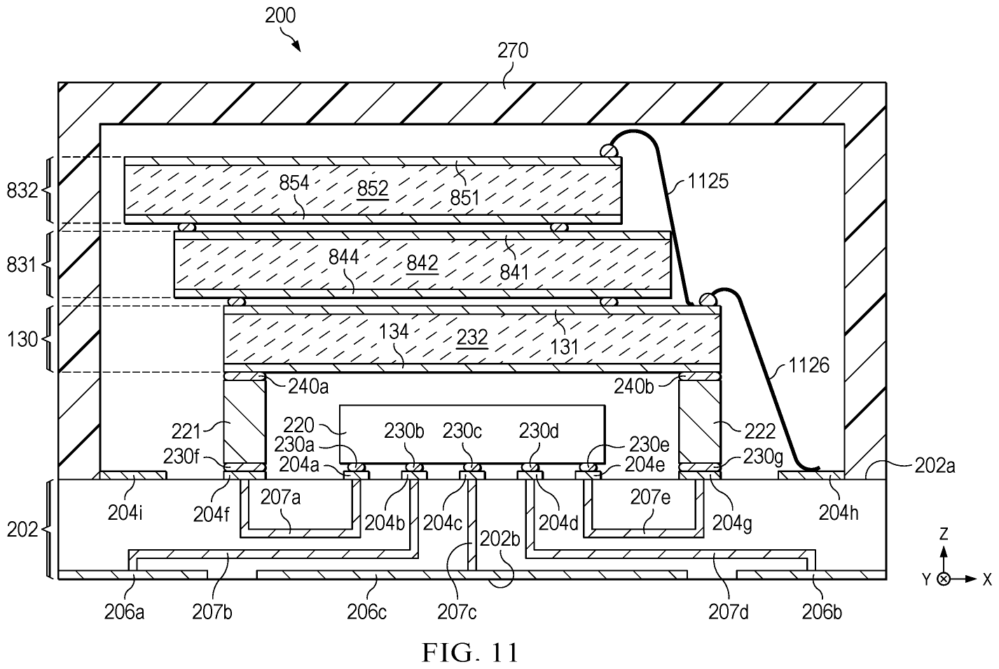

FIG. 11 is a cross-sectional view of a packaged IC 200 in which piezoelectric resonators 130, 831, and 832 are vertically arranged in an offset configuration. A bond wire 1125 electrically couples the top electrode 851 of piezoelectric resonator 832 to the top electrode 131 of piezoelectric resonator 130. A bond wire 1135 electrically couples the top electrode 131 of piezoelectric resonator 130 to metal pad 204h. The remaining electrodes 854, 841, 844, and 134 can be electrically coupled to separate metal pads 204 on the package substrate 202 by way of vias and metal support structures as described above. Ribbon bonding and clip bonding can be used as alternatives to bond wires. The arrangement of FIG. 11 allows for piezoelectric resonators 832 and 130 to be connected in parallel.

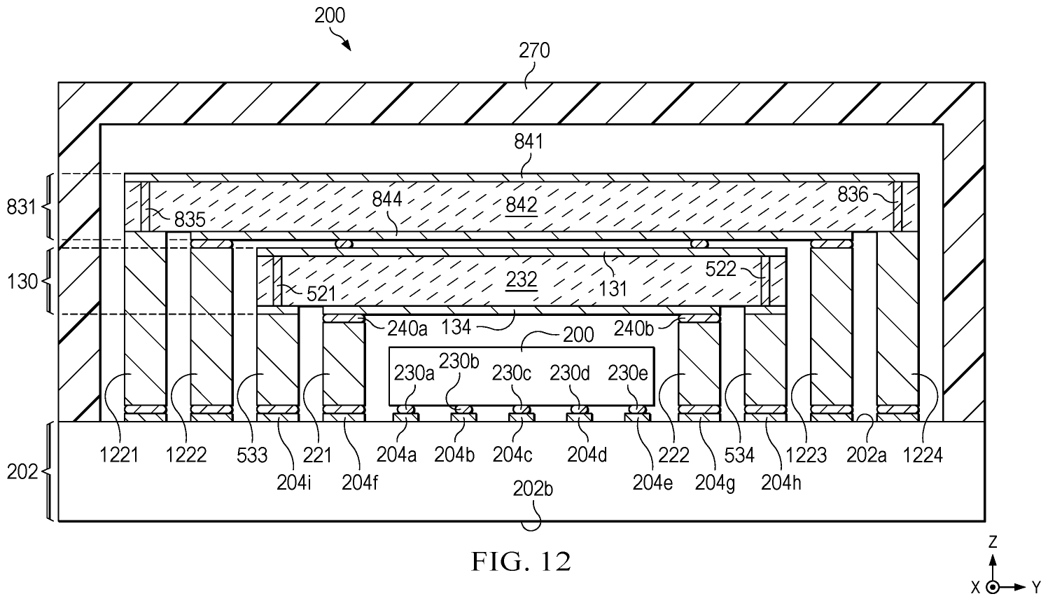

FIG. 12 is a cross-sectional view of packaged IC 200 in which top electrode 841 of piezoelectric resonator 831 is electrically coupled to metal support structures 1221 and 1224 by way of vias 835 and 836, respectively. Bottom electrode 844 is coupled to package substrate 202 by way of metal support structures 1222 and 1223. Metal support structures 1221 and 1224 are taller than metal support structures 122 and 1223, and metal support structures 122 and 1223 are taller than metal support structures 221, 222, 533 and 534.

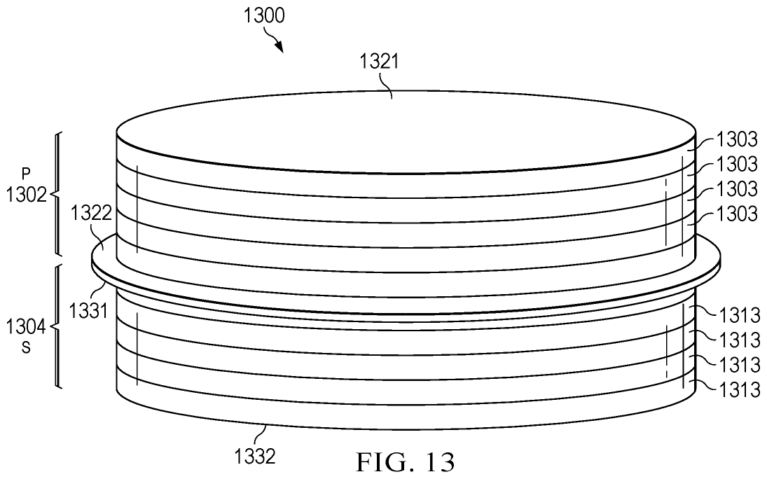

FIG. 13 is an example of a transformer 1300 formed through a primary (P) stack 1302 of piezoelectric resonators 1303 and a secondary(S) stack 1304 of piezoelectric resonators 1313. Each stack 1302 and 1304 includes one or more piezoelectric resonators. The number of piezoelectric resonators in stacks 1302 and 1304 may be the same or different depending on whether the transformer is to be used to step up or down the input voltage. The piezoelectric resonators 1303 and 1313 of stacks 1302 and 1304 may be electrically connected in parallel or in series, or a combination of parallel and series connections. Any of the configurations described with respect to FIGS. 8-12 can be used to implement the multi-piezoelectric resonator stack of each side, primary and secondary, of transformer 1300. The top electrode of the top-most piezoelectric resonator 1303 and the bottom electrode of the bottom-most piezoelectric resonator 1303 in stack 1302 provide the terminals 1321 and 1322 for the primary side of transformer 1300. Similarly, the top electrode of the top-most piezoelectric resonator 1313 and the bottom electrode of the bottom-most piezoelectric resonator 1103 in stack 1304 provide the terminals 1331 and 1332 for the secondary side of the transformer.

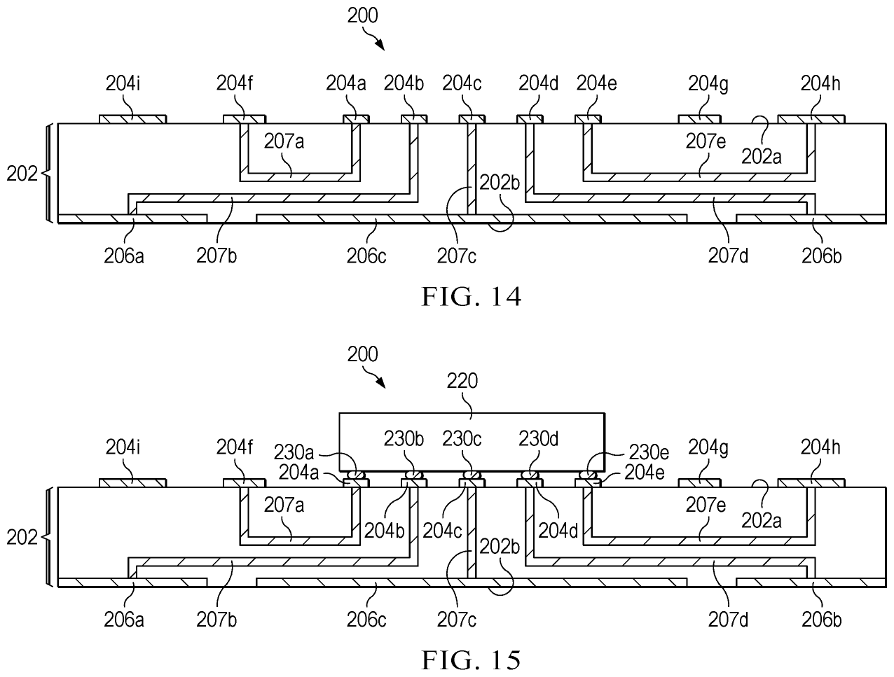

FIGS. 14-19 are cross-sectional views at varying stages of formation of the packaged IC 200 which includes a single piezoelectric resonator. Additional steps can be performed if multiple piezoelectric resonators are to be included in the packaged IC.

FIG. 14 illustrates package substrate 202 including metal pads 204a-204g, 206a, and 206b interconnected by metal interconnects 207. In FIG. 15, semiconductor die 220 is attached (e.g., by a pick-and-place operation of a flip-chip die) to the package substrate 202. Solder 220a can be heated to establish an electrical connection between terminals of semiconductor die 220 and the corresponding metal pads on the package substrate 202.

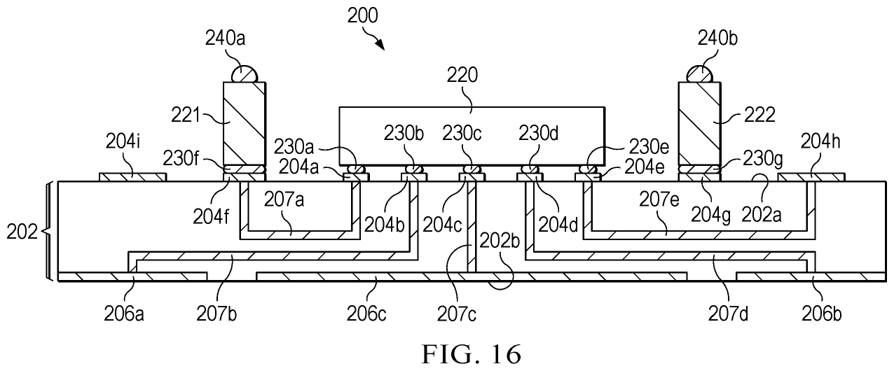

In FIG. 16, metal support structures 221 and 222 are provided, for example, on package substrate 202 on either side of semiconductor die 220. In one example, the metal support structures 221 and 222 can be provided on package substrate 202 by a pick-and-place operation.

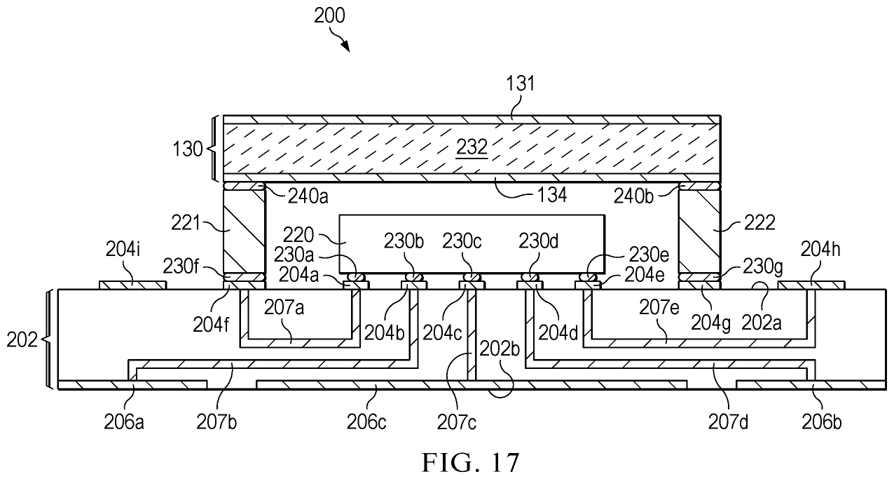

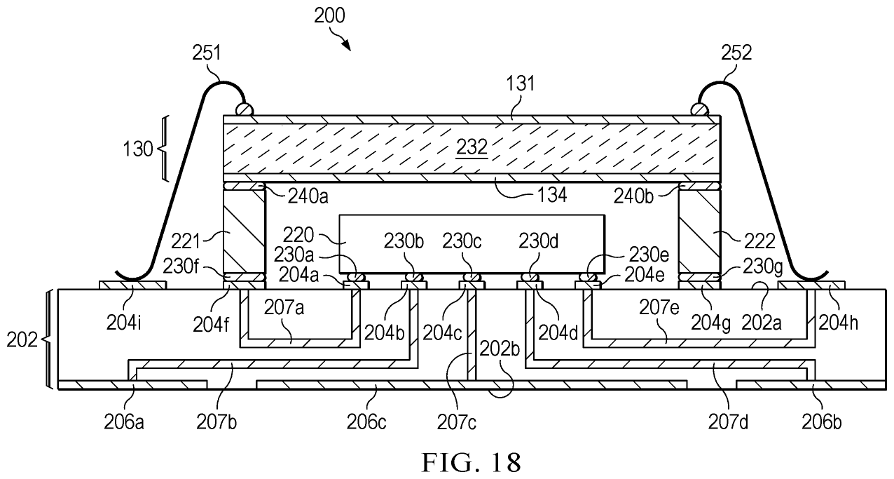

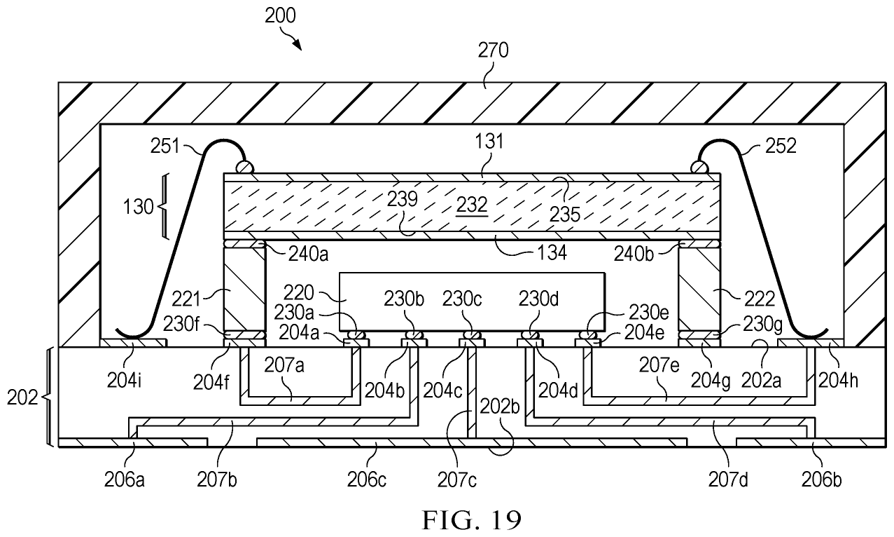

In FIG. 17, piezoelectric resonator 130 is placed (e.g., by a pick-and-place operation) on metal support structures 221 and 222. In FIG. 18, bond wires 251 and 252 can then be soldered to the top electrode 131 of piezoelectric resonator 130 and to the metal pads 204g and 204h on the package substrate 202. Finally, in FIG. 19, cap 270 is placed on package substrate 202. Cap 270 may be adhered to the package substrate by, for example, an adhesive.

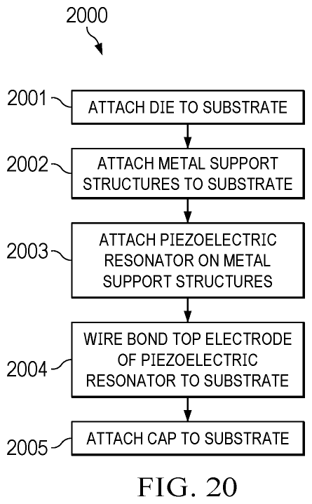

FIG. 20 is a flow chart 2000 illustrating the fabrication operations depicted in FIGS. 14-19. In operation 2001, the semiconductor die 220 is attached to package substrate 202. In operation 2002, metal support structures (e.g., metal support structures 221 and 222) are attached to the package substrate 202. In operation 2003, the piezoelectric resonator (e.g., piezoelectric resonator 130) is attached to the metal support structures. In operation 2004, the top electrode of the piezoelectric resonator is wire-bonded to the package substrate. In operation, 2005, cap 270 is attached to the package substrate thereby covering the piezoelectric resonator and semiconductor die 220.

In this description, the term “couple” may cover connections, communications, or signal paths that enable a functional relationship consistent with this description. For example, if device A generates a signal to control device B to perform an action: (a) in a first example, device A is coupled to device B by direct connection; or (b) in a second example, device A is coupled to device B through intervening component C if intervening component C does not alter the functional relationship between device A and device B, such that device B is controlled by device A via the control signal generated by device A.

Also, in this description, the recitation “based on” means “based at least in part on.” Therefore, if X is based on Y, then X may be a function of Y and any number of other factors.

A device that is “configured to” perform a task or function may be configured (e.g., programmed and/or hardwired) at a time of manufacturing by a manufacturer to perform the function and/or may be configurable (or reconfigurable) by a user after manufacturing to perform the function and/or other additional or alternative functions. The configuring may be through firmware and/or software programming of the device, through a construction and/or layout of hardware components and interconnections of the device, or a combination thereof.

As used herein, the terms “terminal”, “node”, “interconnection”, “pin” and “lead” are used interchangeably. Unless specifically stated to the contrary, these terms are generally used to mean an interconnection between or a terminus of a device element, a circuit element, an integrated circuit, a device or other electronics or semiconductor component.

Uses of the phrase “ground” in the foregoing description include a chassis ground, an Earth ground, a floating ground, a virtual ground, a digital ground, a common ground, and/or any other form of ground connection applicable to, or suitable for, the teachings of this description. In this description, unless otherwise stated, “about,” “approximately” or “substantially” preceding a parameter means being within +/−10 percent of that parameter or, if the parameter is zero, a reasonable range of values around zero.

Modifications are possible in the described examples, and other examples are possible, within the scope of the claims.

What is claimed is:

1. A packaged integrated circuit (IC) comprising:
a package substrate having opposing first and second surfaces, the package substrate including first metal pads and second metal pads on the first surface, third metal pads on the second surface, and metal interconnects coupled between the third metal pads and at least some of the first and second metal pads;
a semiconductor die on the first surface and coupled to the first metal pads;
metal support structures on the first surface and coupled to at least some of the second metal pads;
a piezoelectric resonator on the metal support structures and over the semiconductor die; and
a cap on the package substrate and covering the piezoelectric resonator, the metal support structures, and the semiconductor die.

2. The packaged IC of claim 1, wherein:
the semiconductor die includes a controller of a power converter;
the third metal pads provide electrical connections to an input power terminal, an output power terminal, and a ground terminal of the power converter;
the first metal pads provide electrical connections to a first electrode terminal and a second electrode terminal of the piezoelectric resonator, the input power terminal, the output power terminal, and the ground terminal; and
the second metal pads provide electrical connections to the first and second electrode terminals.

3. The packaged IC of claim 2, wherein the piezoelectric resonator has opposing top and bottom surfaces of a piezoelectric material, the top surface facing the cap and the bottom surface facing the package substrate; and
wherein the piezoelectric resonator includes a top electrode on the top surface and a bottom electrode on the bottom surface, the top electrode electrically coupled to the first electrode terminal, and the bottom electrode electrically coupled to the second electrode terminal via a subset of the metal support structures.

4. The packaged IC of claim 3, wherein the metal support structures are coupled to a first subset of the second metal pads, and the packaged IC further comprises a bond wire, a ribbon, or a clip electrically coupled between the top electrode and a second subset of the second metal pads, the bond wire, ribbon, or clip covered by the cap.

5. The packaged IC of claim 4, wherein the metal support structures include a first metal support structure and a second metal support structure, the first metal support structures electrically coupled to the first electrode terminal, and the second metal support structure electrically coupled to the second electrode terminal; and
wherein the packaged IC further comprises a first metal via and a second metal via through the piezoelectric resonator, and the top electrode is electrically coupled to the first metal support structure via the first metal via, and the bottom electrode is electrically coupled to the second metal support structure and the second metal via.

6. The packaged IC of claim 3, wherein the piezoelectric resonator includes a metal ring on the top surface surrounding at least part of the top electrode, the metal ring electrically isolated from the top electrode.

7. The packaged IC of claim 6, wherein the metal ring is electrically coupled to the ground terminal.

8. The packaged IC of claim 2, wherein the metal support structures are first metal support structures, the piezoelectric resonator is a first piezoelectric resonator, and the packaged IC further comprises:
second metal support structures on the first piezoelectric resonator or on the first surface of the package substrate; and
a second piezoelectric resonator on the second metal support structures; and
wherein the second metal support structures and the second piezoelectric resonator are covered by the cap.

9. The packaged IC of claim 8, wherein the first piezoelectric resonator has opposing first top and bottom surfaces, the first piezoelectric resonator including a first top electrode on the first top surface and a first bottom electrode on the first bottom surface; and
wherein the second piezoelectric resonator has opposing second top and bottom surfaces, the second bottom surface facing the first top surface, the second piezoelectric resonator including a second top electrode on the second top surface and a second bottom electrode on the second bottom surface.

10. The packaged IC of claim 9, further comprising first metal vias in the first piezoelectric resonator and second metal vias in the second piezoelectric resonator, wherein:
the second metal support structures are on the first surface;
the first bottom electrode is electrically coupled to a first subset of the first metal support structures;
the first top electrode is electrically coupled to a second subset of the first metal support structures via a first subset of the first metal vias;
the second bottom electrode is electrically coupled to a first subset of the second metal support structures via a first subset of the second metal vias; and
the second top electrode is electrically coupled to a second subset of the second metal support structures via a second subset of the second metal vias.

11. The packaged IC of claim 9, further comprising first metal vias in the first piezoelectric resonator and second metal vias in the second piezoelectric resonator, wherein:
the second metal support structures are on the first piezoelectric resonator;
the first bottom electrode is electrically coupled to a first subset of the first metal support structures;
the first top electrode is electrically coupled to a second subset of the first metal support structures via a first subset of the first metal vias;
the second bottom electrode is electrically coupled to the second subset of the first metal support structures via a first subset of the second metal support structures; and
the second top electrode is electrically coupled to a third subset of the first metal support structures via the second metal vias, a second subset of the second metal support structures, and a second subset of the first metal vias.

12. The packaged IC of claim 9, further comprising bond wires, ribbons, or clips, wherein:
the second metal support structures are on the first piezoelectric resonator;
the first bottom electrode is electrically coupled to a first subset of the second metal pads via the first metal support structures;
the first top electrode is electrically coupled to a second subset of the second metal pads via a first subset of the bond wires, ribbons, or clips;
the second bottom electrode is electrically coupled to a third subset of the second metal pads via the second metal support structures and a second subset of the second metal support structures; and
the second top electrode is electrically coupled to a fourth subset of the second metal pads via a third subset of the bond wires, ribbons, or clips.

13. The packaged IC of claim 9, further comprising first metal vias in the first piezoelectric resonator and second metal vias in the second piezoelectric resonator, wherein:
the first metal support structures are electrically coupled to a first subset of the second metal pads;
the second metal support structures are on the first surface and are electrically coupled to a second subset of the second metal pads;
the first bottom electrode is electrically coupled to a first subset of the first metal support structures;
the first top electrode is electrically coupled to a second subset of the first metal support structures via the first metal vias;
the second bottom electrode is electrically coupled to a first subset of the second metal support structures; and
the second top electrode is electrically coupled to a second subset of the second metal support structures via the second metal vias.

14. The packaged IC of claim 8, wherein the first and second piezoelectric resonators are part of a transformer.

15. The packaged IC of claim 1, wherein the metal support structures include metal posts or metal sheets.

16. The packaged IC of claim 1, wherein the metal support structures are below corners of the piezoelectric resonator.

17. The packaged IC of claim 1, wherein the metal support structures are below edges of the piezoelectric resonator.

18. The packaged IC of claim 1, wherein the piezoelectric resonator has opposing top and bottom surfaces of a piezoelectric material, the piezoelectric material includes at least one of lithium niobate, lithium tantalate, lead titanate, or gallium orthophosphate.

19. The packaged IC of claim 1, wherein the cap comprises at least one of: a metal, silicon, or a fiberglass laminate.

20. A power converter comprising:
a package substrate having an input power terminal, an output power terminal, a ground terminal, a first electrode terminal, and a second electrode terminal;
a controller mounted on the package substrate and is electrically coupled to the input power terminal, the output power terminal, the ground terminal, the first electrode terminal, and the second electrode terminal;
a first metal support structure on the package substrate and electrically coupled to the first electrode terminal;
a second metal support structure on the package substrate and electrically coupled to the second electrode terminal or the ground terminal;
a piezoelectric resonator attached to the first and second metal support structures and over the controller, the piezoelectric resonator having a top electrode electrically coupled to the first electrode terminal and a second electrode electrically coupled to the second electrode terminal.

21. The power converter of claim 20, further comprising a cap on the package substrate and covering the piezoelectric resonator, the first and second metal support structures, and the controller.

22. The power converter of claim 20, wherein the piezoelectric resonator is a first piezoelectric resonator, and the power converter includes a second piezoelectric resonator over the first piezoelectric resonator and electrically coupled to the package substrate.

23. A method of forming a packaged IC comprising:
attaching a semiconductor die on a first surface of a package substrate, in which the semiconductor die is coupled to a first subset of first metal pads, the package substrate having the first surface and an opposing second surface, the package substrate also including first and second metal pads on the first surface, third metal pads on the second surface, and metal interconnects coupled between the third metal pads and at least some of the first and second metal pads;
attaching metal support structures on the first surface, in which the metal support structures are coupled to a second subset of the first metal pads;
attaching a piezoelectric resonator on the metal support structures and over the semiconductor die; and
attaching a cap on the package substrate and covering the piezoelectric resonator, the metal support structures, and the semiconductor die.
